(19) United States
(12) Patent Application Publication
(10) Pub. No.: US 2010/0059812 A1
(43) Pub. Date: Mar. 11, 2010

(54) FLASH MEMORY DEVICE AND METHOD FOR MANUFACTURING THE SAME

(76) Inventor: Jin Ha Park, Gyeonggi-do (KR)

Correspondence Address: Jin Ha Park, 101-601, Jinu Apt., Sinha-ri, Bubal-eup,, Icheon-si, KR

(21) Appl. No.: 12/546,323

(22) Filed: Aug. 24, 2009

(30) Foreign Application Priority Data
Sep. 11, 2008 (KR) 10-2008-0089692

(51) Int. Cl. H01L 29/792; H01L 21/336

(52) U.S. Cl. 257/324; 438/287; 257/E29.309; 257/E21.423

(57) ABSTRACT

Disclosed are a flash memory device and a method for manufacturing the same. The flash memory device includes a semiconductor substrate having a unit cell defined by an isolation layer, a gate formed over the semiconductor substrate, LDD areas formed at shallow areas of the semiconductor substrate at both sides of the gate, a source and a drain formed at deep areas of the semiconductor substrate while making contact with the LDD areas, and spacers formed at sidewalls of the gate. The spacer includes a first oxide layer pattern, a nitride layer pattern, and a second oxide layer pattern, and the semiconductor substrate includes silicon, so that a silicon-oxide-nitride-oxide-silicon structure for the flash memory device is formed by the silicon of the semiconductor substrate and the spacer at the drain side of the gate.

### CROSS-REFERENCE TO RELATED APPLICATION

This application claims the benefit under 35 U.S.C. §119 to Korean Patent Application No. 10-2008-0089692, filed Sep. 11, 2008, which is hereby incorporated by reference in its entirety.

### BACKGROUND

The present disclosure relates to a flash memory device, and more particularly to a one time programmable (OTP) device.

A non volatile memory (NVM) is a device that retains stored data even if power is not supplied thereto, and is selectively programmed according to a user's requirements.

Among the NVMs, a flash memory device is classified into a multi-time programmable (MTP) NVM that is programmed and read several times and a one time programmable (OTP) NVM that is programmned and read one time.

An OTP device is a semiconductor device that performs as an NVM. The OTP device is a next generation of flash memory devices based on an EEPROM (electrically erasable programmable read only memory).

In the OTP device, one cell includes one transistor. In addition, since data of the OTP device is erased by using an ultraviolet ray, additional circuits and processes are not required in a chip to erase the data. Since the OTP device allows only one programming, the OTP is used for a product that must retain data. For example, the OTP device is a core element for a CPU to control house facilities, or for computers or a micro-controller unit (MCU) (e.g. a remote controller) to control all electric and electronic appliances.

Such an OTP device has a non-volatile characteristic, so the OTP device has a stacked gate structure similar to that of the flash device. In other words, the stacked gate structure includes a tunnel oxide, a floating gate, an intergate dielectric layer, and a control gate electrode sequentially formed on a channel area of a cell transistor. The OTP device having the stacked gate structure requires several process steps, as well as an additional process to form a transistor in a logic area.

Since the device having the stacked gate structure stores charges in the floating gate, retention time may be remarkably reduced even if micro-defects occur in the floating gate.

### BRIEF SUMMARY

An embodiment provides a flash memory device capable of trapping hot electrons by a nitride layer of an ONO spacer having the same structure as that of a logic area and a method for manufacturing the same.

According to an embodiment, the flash memory device includes a semiconductor substrate having a unit cell defined by an isolation layer; a gate formed over the semiconductor substrate; LDD areas formed at shallow areas of the semiconductor substrate at both sides of the gate; a source and a drain formed at deep areas of the semiconductor substrate while making contact with the LDD areas; and spacers formed at sidewalls of the gate, wherein the spacer includes a first oxide layer pattern, a nitride layer pattern, and a second oxide layer pattern, and the semiconductor substrate includes silicon, so that a silicon-oxide-nitride-oxide-silicon (SONOS) structure is formed using the spacers at the drain side of the gate.

According to an embodiment, a method for manufacturing a flash memory device includes forming an isolation layer on a semiconductor substrate including silicon; forming a gate on the semiconductor substrate; forming LDD areas at shallow areas of the semiconductor substrate at both sides of the gate; forming a spacer, which includes a first oxide layer pattern, a nitride layer pattern, and a second oxide layer pattern, at sidewalls of the gate; and forming a source and a drain at deep areas of the semiconductor substrate while making contact with the LDD areas, wherein the semiconductor substrate, the first oxide layer pattern, the nitride layer pattern, and the second oxide layer pattern form a SONOS structure at the drain side of the gate.

### BRIEF DESCRIPTION OF THE DRAWINGS

FIGS. 1 to 5 are cross-sectional views showing a method for manufacturing a flash memory according to the embodiment; and

FIG. 6 is an enlarged view of area A of FIG. 5 showing the operation of a flash memory device according to an embodiment.

### DETAILED DESCRIPTION

Hereinafter, a flash memory device and a method for manufacturing the same will be described in detail with reference to accompanying drawings.

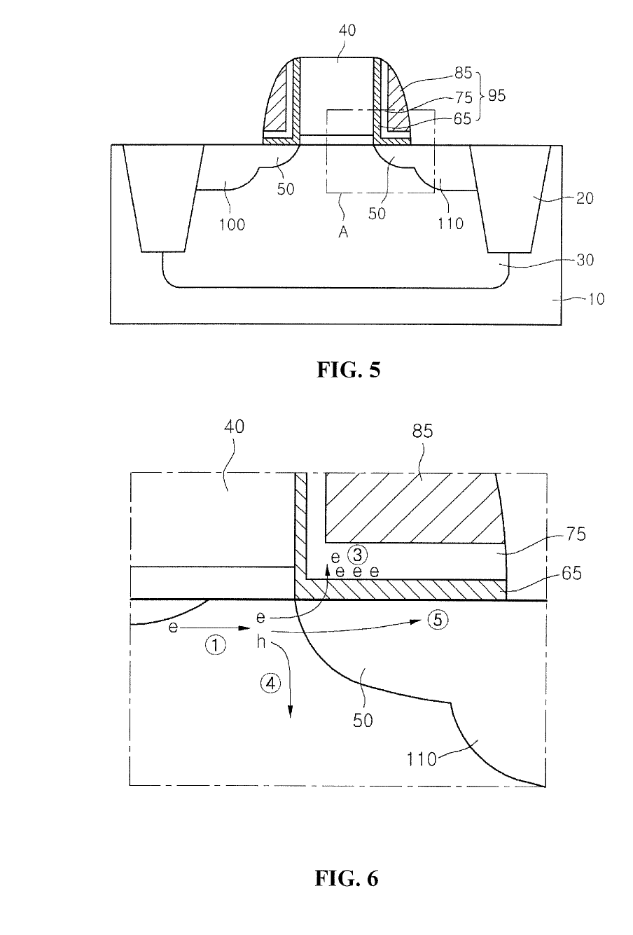

FIG. 5 is a cross-sectional view showing a flash memory device according to an embodiment of the present invention.

Referring to FIG. 5, a flash memory device can include a semiconductor substrate 10 in which unit cells are defined by an isolation layer 20; a gate 40 formed on the semiconductor substrate 10; lightly doped drain (LDD) areas 50 formed at shallow areas of the semiconductor substrate 10 at both sides of the gate 40; a source 100 and a drain 110 formed at deeper areas of the semiconductor substrate 10 while making contact with the LDD areas 50; and spacers 95 formed at sidewalls of the gate 40. The spacer 95 includes a first oxide layer pattern 65, a nitride layer pattern 75, and a second oxide layer pattern 85; and the semiconductor substrate 10 includes silicon, so that a silicon-oxide-nitride-oxide-silicon (SONOS) structure can be formed.

In an embodiment for an NMOS type OTP device, a P-well 30 is formed below the gate 40, and the source 100 and the drain 110 may be implanted with n-type impurities such as arsenic (As) and phosphorous (P).

The OTP device can be programmed such that electrons moving from the source 100 to the drain 110 are trapped in the nitride layer pattern 75 corresponding to the drain 110 if a bias voltage is applied to the gate 40 and the drain 110.

Accordingly, since the nitride layer pattern 75 traps electrons like a floating gate in the flash memory device having a stacked gate structure, the nitride layer pattern 75 can be used in the OTP device.

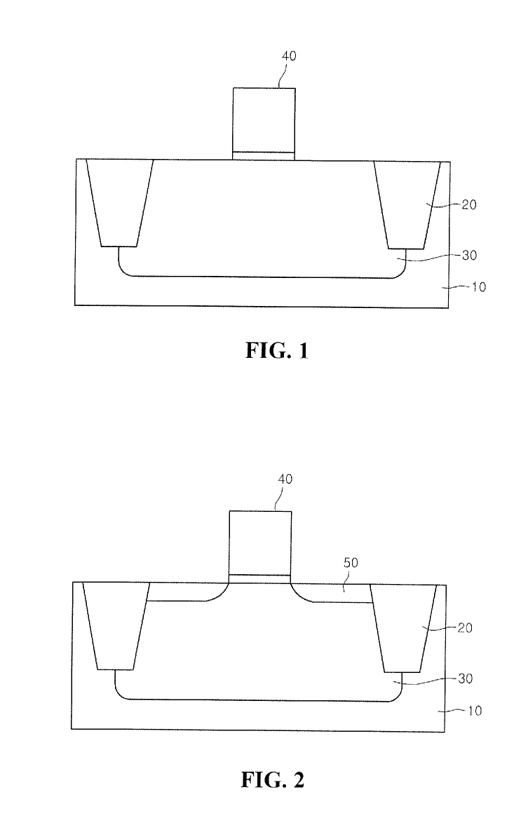

Hereinafter, a flash memory device and a method for manufacturing the same according to an embodiment will be described with reference to FIGS. 1 to 5. The following description is made regarding only the forming of a unit cell of an OTP device. A transistor of a logic area may also be formed when forming the OTP device.

Referring to FIG. 1, an isolation layer 20 is formed on the semiconductor substrate 10 to define a unit cell.

The isolation layer 20 is formed on the semiconductor substrate 10 through, for example, a LOCOS process or an STI process, and an active area is defined by the isolation layer 20.

An ion implantation process is performed to form an NMOS device or a PMOS device in an active area of the semiconductor substrate 10. According to an embodiment, in order to form the NMOS device, a P-well 30 may be formed in the semiconductor substrate 10. For example, the P-well 30 may be formed by implanting ions belonging to group III elements, such as boron, and performing a heat treatment process for the resultant structure.

Next, after depositing a gate insulating layer and a gate conductive layer on the semiconductor substrate 10, the resultant structure is patterned to form the gate 40. For example, the gate insulating layer may include an oxide layer, and the gate insulating layer may include polysilicon.

Although not shown, before the gate 40 is formed, a channel area may be formed by lightly doping impurities onto the surface of the semiconductor substrate 10.

Referring to FIG. 2, LDD areas 50 are formed at shallow areas of the semiconductor substrate 10 positioned at both sides of the gate 40.

The LDD area 50 may be formed by implanting dopants with low concentration using the gate 40 as an ion implantation mask. For example, the LDD area 50 may be formed by implanting ions belonging to group V elements, such as arsenic (As) or phosphorus (P), into a shallow area of the semiconductor substrate 10 such that hot electrons (i.e., hot carriers) are formed.

For example, the LDD area 50 may be formed by implanting As at a dose of 1×10¹³ to 1×10¹⁴ ion/cm² under energy of 15 keV to 25 keV. Although not shown, an LDD area of a transistor in a logic area may be formed by implanting As at a dose of 1×10¹³ to 1×10¹⁴ ion/cm² under energy of 30 keV to 60 keV. In other words, the concentration of impurities of the LDD area 50 corresponding to a unit pixel of the OTP device is higher than that of the LDD area (not shown) of the logic area (not shown), so that implant junction engineering can be increased.

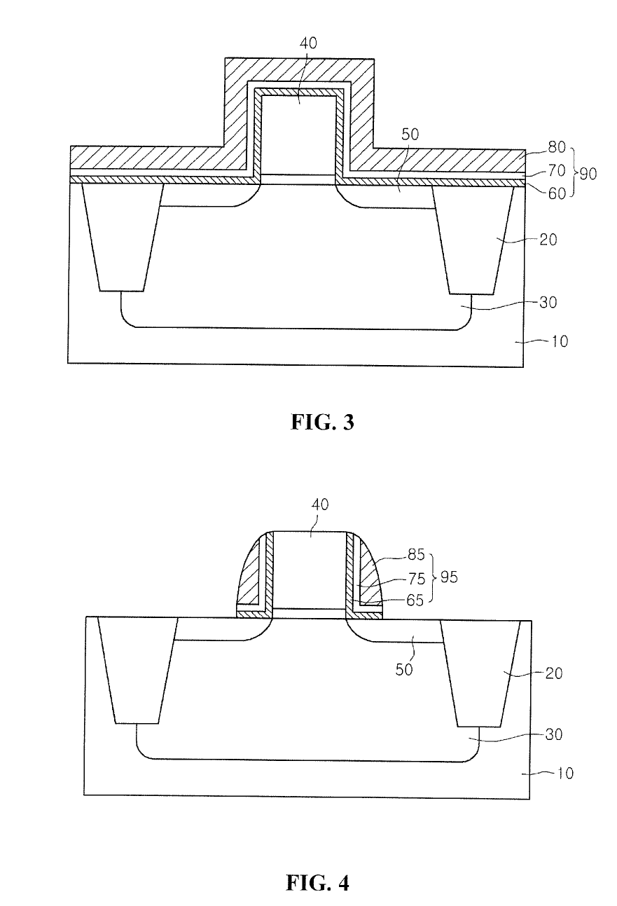

Referring to FIG. 3, a spacer layer 90 is formed to isolate and protect the gate 40.

The spacer layer 90 may be formed by sequentially depositing a first oxide layer 60, a nitride layer 70, and a second oxide layer 80 on the semiconductor substrate 10 formed with the gate 40. In other words, the spacer layer 90 may have an ONO structure.

Referring to FIG. 4, a spacer 95 is formed at a sidewall of the gate 40. The spacer 95 may be formed by etching the entire surface of the spacer layer 90 through, for example, an etchback process.

Accordingly, the spacer 95 may include a first oxide layer pattern 65, a nitride pattern 75, and a second oxide layer pattern 85.

Since the spacer 95 having an oxide-nitride-oxide layer structure is formed on the semiconductor substrate 10, the semiconductor substrate 10 and the spacer 95 have a structure similar to the SONOS structure.

The semiconductor substrate 10 is a silicon substrate, and the spacer 95 has the oxide-nitride-oxide layer structure. Accordingly, the nitride layer pattern 75 of the spacer 95 can serve as a nitride layer storing charges in a memory device having the typical SONOS structure.

In other words, according to embodiments of the present invention, the nitride layer may be used as a floating gate of a flash memory device in the form of the SONOS structure by performing the same processes as for the logic area. In operation, the electrons are injected into the nitride layer of the spacer in the drain area according to voltage conditions of the drain and the gate.

Therefore, according to an embodiment, since the nitride layer pattern 75 of the spacer 95 can trap electrons, the nitride layer pattern 75 can be adopted in the OPT device.

Referring to FIG. 5, a source 100 and a drain 110 are formed at both sides of the gate 40 while making contact with the LDD areas 50. The source 100 and the drain 110 may be formed by implanting impurities with high concentration into a deep area of the semiconductor substrate 10 by using both the gate 40 and the spacer 95 as a mask. For example, the source 100 and the drain area 110 may be formed by implanting ions belonging to group V elements, such as As or P, into deep areas of the semiconductor substrate 10.

Since As or P is used as the dopant for the source 100 and the drain 110, an implant junction may be realized to excessively generate electron-hole pairs (EHP).

The OTP device according to an embodiment makes a high doping level difference between the LDD area 50 and the semiconductor substrate 10, thereby increasing the intensity of an electric field.

Although not shown, the transistor of the logic area may be simultaneously formed when the transistor of the cell area is formed.

FIG. 6 is an enlarged view of portion A of FIG. 5, showing the OTP device.

Hereinafter, a process of trapping electrons when programming the OPT device will be described with reference to FIG. 6.

A positive voltage is applied to both the gate 40 and the drain 110 such that gate induced drain leakage (GIDL) can be sufficiently reduced. For example, a bias condition is as follows. A voltage of 4V to 7V is applied to the gate 40, and a voltage of 3V to 5V is applied to the drain 110 such that the source 100 and the semiconductor substrate 10 can be grounded. For example, the logic area may be used in a logic produce having a voltage of 3.3V.

If a bias voltage is applied to the drain 110 in a state in which the bias voltage is applied to the gate 40, a pinch-off phenomenon occurs. Accordingly, an electric field is generated along a channel from the source 100 to the drain 110, and electrons (e) flow the channel from the source 100 to the drain 110 by the electric field.

As the electrons (e) flow along the channel, and electron hole pairs (E-H-P) are formed by the strong electric field. When the bias voltage of the drain 110 is weak, the electrons (e) that have passed through the channel flow to the drain 110 through \textcircled{1}\textcircled{5} path. And, the holes (h) that have passed through the channel flow to the semiconductor substrate 10 through \textcircled{4} path. In contrast, when the bias voltage of the drain 110 is increased, the electrons (e) obtain great energy, so that the electrons (e) can be trapped in the nitride layer pattern 75 through \textcircled{3} path. The electrons (e) obtain energy while moving along the channel. In particular, electrons (e) can obtain great energy in the channel area in the vicinity of the drain 110. If the bias voltage of the drain 110 is increased, the electrons (e) are hot enough to enter a charge trap layer. As a result, the electrons (e) serve as hot electrons. This program scheme is called hot carrier injection.

Therefore, the hot electrons (e) are trapped in the nitride layer pattern 75 corresponding to the drain area and including an insulating material, and stored in the nitride layer pattern 75 so that the electrons (e) can be programmed. In addition, both forward read and reverse read schemes are possible.

The OTP device can be formed through the same processes as that of the logic circuitry without using the complex process required for a SONOS structure or a stacked gate structure according to the related art, so that the manufacturing process can be simplified.

In other words, the OTP device can be realized by employing the ONO structure of the logic area while using the nitride layer as a charge storage area similarly to the SONOS structure.

Further, since the nitride layer is used as the charge storage area, the OTP device is less affected by defects in the manufacturing process.

In addition, when the logic area is formed, the OTP device is simultaneously formed in the cell area, so that the manufacturing process is simplified. Accordingly, the productivity can be improved.

The OTP device according to an embodiment can be realized through implant junction engineering. The implant junction engineering is to increase a doping concentration of an n+ area, which is a drain area of the OTP device. By the implant junction engineering, a doping level difference is made with a p-type area that is the semiconductor substrate, so that the intensity of an electric field is increased, thereby increasing a programming efficiency of the OTP device. In addition, the drain area of the OTP device receives a bias higher than that of the logic area, so that the programming efficiency can be increased.

In the OTP device, a highly charged ion (HCI) characteristic and an insulating characteristic can be maintained.

It should be understood that the examples and embodiments described herein are for illustrative purposes only and that various modifications or changes in light thereof will be suggested to persons skilled in the art and are to be included within the spirit and purview of this application.

What is claimed is:

1. A flash memory device comprising:
a semiconductor substrate having a unit cell defined by an isolation layer, wherein the semiconductor substrate comprises silicon;
a gate formed over the semiconductor substrate within the unit cell;
LDD areas formed at shallow areas of the semiconductor substrate at both sides of the gate;
a source and a drain formed at deep areas of the semiconductor substrate while making contact with the LDD areas; and
spacers formed at sidewalls of the gate,
wherein the spacers include a first oxide layer pattern, a nitride layer pattern, and a second oxide layer pattern, whereby a silicon-oxide-nitride-oxide-silicon (SONOS) structure is provided for the flash memory device by the silicon of the semiconductor substrate and the spacer at the sidewall at a drain side of the gate.

2. The flash memory device of claim 1, wherein electrons moving from the source to the drain are trapped into the nitride layer pattern at the drain side of the gate and programmed if a bias voltage is applied to both the gate and the drain.

3. The flash memory device of claim 1, wherein the source and the drain include n-type impurities including arsenic or phosphorus.

4. A method for manufacturing a flash memory device, the method comprising:
forming an isolation layer on a semiconductor substrate, the semiconductor substrate comprising silicon;
forming a gate on the semiconductor substrate;
forming LDD areas at shallow areas of the semiconductor substrate at both sides of the gate;
forming a spacer, which includes a first oxide layer pattern, a nitride layer pattern, and a second oxide layer pattern, at sidewalls of the gate; and
forming a source and a drain at deep areas of the semiconductor substrate while making contact with the LDD areas,
wherein the semiconductor substrate, the first oxide layer pattern, the nitride layer pattern, and the second oxide layer pattern provide a SONOS structure for the flash memory device.

5. The method of claim 4, wherein the forming of the spacer comprises:
sequentially forming a first oxide layer, a nitride layer, and a second oxide layer on the semiconductor substrate including the gate; and
forming the first oxide layer pattern, the nitride layer pattern, and the second oxide layer pattern by etching an entire surface of the first oxide layer, the nitride layer, and the second oxide layer by an etchback process.

6. The method of claim 4, wherein the forming of the source and the drain comprises implanting n-type dopants including arsenic or phosphorus in deep areas of the semiconductor substrate using the gate and the spacer as a mask.

7. The method of claim 4, further comprising forming a P-well in the semiconductor substrate at a region corresponding to a unit cell after forming the isolation layer, wherein the gate is formed on the P-well.
